(19) United States
(12) Patent Application Publication
(10) Pub. No.: US 2014/0052390 A1
(43) Pub. Date: Feb. 20, 2014

(54) APPARATUS AND METHOD FOR DETECTING ERROR AND VARIATION IN LIGHT-EMITTING DIODE LIGHTTING

(71) Applicant: Electronics and Telecommunications Research Institute, Daejeon-city (KR)

(72) Inventors: You-Jin KIM, Daejeon (KR); Tae-Gyu KANG, Daejeon (KR); Dae-Ho KIM, Daejeon (KR); Hyun-Seok KIM, Daejeon (KR); Hyun-Jong KIM, Cheongju-si (KR); Sang-Kyu LIM, Daejeon (KR); Il-Soon JANG, Daejeon (KR); Jin-Doo JEONG, Daejeon (KR); In-Su KIM, Daejeon (KR); Seong-Hee PARK, Daejeon (KR)

(21) Appl. No.: 13/939,705

(22) Filed: Jul. 11, 2013

(30) Foreign Application Priority Data
Aug. 16, 2012 (KR) 10-2012-0089265

(51) Int. Cl. G01R 31/44

(52) U.S. Cl. CPC G01R 31/44
USPC 702/58

(57) ABSTRACT

Disclosed herein are an apparatus and method for sensing an error and a variation in Light-Emitting Diode (LED) lighting. In the method, a PWM signal including required light emission information is generated. Tail data including operation information is generated. A CRC value based on the tail data is also generated. A tail-CRC signal is generated by combining the tail data with the CRC value. Finally, a PWM-tail signal is generated by combining the tail-CRC signal with the PWM signal.

### CROSS REFERENCE TO RELATED APPLICATION

This application claims the benefit of Korean Patent Application No. 10-2012-0089265, filed on Aug. 16, 2012, which is hereby incorporated by reference in its entirety into this application.

### BACKGROUND OF THE INVENTION

1. Technical Field

The present invention relates generally to an apparatus and method for detecting an error and a variation in Light-Emitting Diode (LED) lighting and, more particularly, to an apparatus and method that can determine an error and a failure in LED lighting in a lighting apparatus using an LED and can detect a variation in a lighting environment in a lighting area.

2. Description of the Related Art

A conventional technology determines the failure of an LED lighting apparatus by detecting a variation in current in the LED lighting apparatus.

Referring to FIG. 1 illustrating the conventional technology, a lighting apparatus 1010 receives a control instruction from a lighting control server over a communication line 1020. The lighting apparatus 1010 interprets the control instruction using a communication unit 1030, and controls a power driver unit 1050 using a control unit 1040. As a result of the control, a light emission unit 1060 emits light as indicated by reference numeral 1070. In general, the control unit 1040 controls the power driver unit 1050 using a current control scheme or a Pulse Width Modulation (PWM) control scheme.

In the conventional technology, the power driver unit 1050 receives feedback on the state of a constant-current from the light emission unit 1060, and determines the occurrence of an error based on a variation in current. Further, the dimming of the light emission unit 1060 is controlled based on the amount of current.

Referring to FIG. 2, the conventional PWM control scheme controls the dimming of the light emission unit 1060 at the ratio of each of various duty cycles 1080, 1090 and 1100 by controlling the On/Off operations of the light emission unit 1060 in accordance with the duty cycle ratio.

The conventional scheme for sensing a failure using a variation in current in an LED lighting apparatus is inefficient in that it does not maximally utilize the advantage of an LED light source, that is, applicable visible-light communication (VLC) that can be applied based on the characteristic of an LED that allows the LED to be switched on/off at high speed.

Korean Patent Application Publication No. 2012-0003793 discloses “Failure Detection System and Method for LED Lighting Equipment.” The technology disclosed in the patent application publication determines whether a lighting apparatus is normally operated by measuring a current value and the operating parameters of an LED. However, the technology disclosed in the above patent application publication has limitations in that it does not utilize the above-described advantage of an LED light source.

Therefore, there is a need for technology that is capable of detecting various types of errors in a lighting apparatus and a variation in a lighting environment in a lighting area.

### SUMMARY OF THE INVENTION

Accordingly, the present invention has been made keeping in mind the above problems occurring in the prior art, and an object of the present invention is to provide an apparatus and method that determine an error and a failure in LED lighting in a lighting apparatus using one or more LEDs and detect a variation in a lighting environment in a lighting area.

In accordance with an aspect of the present invention, there is provided a method of detecting an error and a variation in LED lighting, the method including generating a PWM signal including required light emission information; generating tail data including operation information; generating a CRC value based on the tail data; generating a tail-CRC signal by combining the tail data with the CRC value; and generating a PWM-tail signal by combining the tail-CRC signal with the PWM signal.

The method may further include extracting a tail signal from the PWM-tail signal; and checking the validity of the extracted tail signal and then reporting results of the checking to a lighting control server.

Checking the validity of the extracted tail signal and then reporting the results of the checking to the lighting control server may include, if the tail signal is valid, counting the tail data of the tail signal and then recording a time for which lighting has been used; and reporting the time for which lighting has been used to the lighting control server.

Checking the validity of the extracted tail signal and then reporting the results of the checking to the lighting control server may include, if the tail signal is invalid, determining that a lighting control error has occurred; and reporting the lighting control error to the lighting control server.

The method may further include supplying electric power to a light emission unit in response to the PWM-tail signal; and emitting light from the light emission unit in response to the supplied electric power.

The method may further include collecting the light emitted from the light emission unit; sensing illuminance and color of the collected light; comparing the sensed illuminance and color of the light with the required light emission information; and reporting to the lighting control server whether a light output error has occurred based on the results of the comparison that are obtained by the comparing the sensed illuminance and color of the light with the required light emission information.

The method may further include collecting the light emitted from the light emission unit; converting the collected light into an electrical signal including a frequency component; extracting a tail signal from the electrical signal; and checking validity of the extracted tail signal, and then reporting results of the checking to a lighting control server.

Checking the validity of the extracted tail signal, and then reporting the results of the checking to the lighting control server may include, if the tail signal is invalid, determining that an environmental variation has occurred; and reporting the environmental variation to the lighting control server.

The method may further include collecting the light emitted from the light emission unit; converting the collected light into an electrical signal including a frequency component; converting the electrical signal into a digital voltage level into the frequency component has been incorporated; comparing the digital voltage level with a predetermined threshold voltage; and reporting to a lighting control server whether an environmental variation has occurred based on results of the comparison obtained by comparing the digital voltage level with the predetermined threshold voltage.

Reporting to the lighting control server whether the environmental variation has occurred based on the results of the comparison may include, if the digital voltage level is lower than the predetermined threshold voltage, determining that the environmental variation has occurred; and reporting the environmental variation to the lighting control server.

The method may further include collecting the light emitted from the light emission unit; sensing illuminance and color of the collected light; extracting the average values of the illuminance and the color by storing the sensed illuminance and color of the light over a predetermined time; comparing the average values of the illuminance and the color with the required light emission information; and reporting to the lighting control server whether an environmental variation has occurred based on results of the comparison obtained by comparing the average values of the illuminance and the color with the required light emission information.

Reporting to the lighting control server whether the environmental variation has occurred based on the results of the comparison may include, if the average values of the illuminance and the color are different from the required light emission information, determining that the environmental variation has occurred; and reporting the environmental variation to the lighting control server.

The operation information may include a tail identifier, a lighting identifier, a tail sequence value, and user instruction information.

In accordance with another aspect of the present invention, there is provided an apparatus for detecting an error and a variation in LED lighting, the apparatus including a communication unit configured to make communication with a lighting control server over a lighting control network; a PWM generating unit configured to generate a PWM signal including required light emission information; a PWM-tail processing unit configured to generate tail data including operation information and a CRC value based on the tail data, and to generate a PWM-tail signal by combining the tail data, the CRC value and the PWM signal; a light emission unit configured to emit light using at least one LED; a power driver unit configured to supply electric power to the light emission unit under a control of the PWM-tail signal; an optical feedback unit configured to collect the light emitted from the light emission unit; a photoelectric conversion unit configured to convert the light collected in the optical feedback unit into an electrical signal; and a sensing unit configured to sense illuminance and color of the light collected by the optical feedback unit by using an illuminance sensor and a color sensor.

The PWM-tail processing unit may extract a tail signal from the PWM-tail signal, and check the validity of the extracted tail signal, thereby detecting whether a lighting control error has occurred.

The PWM-tail processing unit may extract a tail signal from the PWM-tail signal, and count tail data of the extracted tail signal, thereby obtaining a time for which lighting has been used.

The PWM-tail processing unit may sense whether a light output error has occurred by comparing the sensed illuminance and color of the light, sensed by the sensing unit, with the required light emission information.

The PWM-tail processing unit may extract a tail signal from the electrical signal obtained by the photoelectric conversion unit, and check the validity of the extracted tail signal, thereby detecting whether an environmental variation has occurred.

The PWM-tail processing unit may convert the electrical signal obtained by the photoelectric conversion unit into a digital voltage level into which a frequency component has been incorporated, and compare the digital voltage level with a predetermined threshold voltage, thereby detecting whether an environmental variation has occurred.

The PWM-tail processing unit may extract average values of the illuminance and color by storing the illuminance and color sensed by the sensing unit over a predetermined time, and compare the average values of the illuminance and the color with the required light emission information, thereby detecting whether an environmental variation has occurred.

An apparatus for detecting an error and a variation in LED lighting may further include a memory configured to store at least one information among manufacture information, installation information, tail data count information and a lighting state self-diagnosis result.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram showing a conventional technology for determining whether the failure of an LED lighting apparatus has occurred by detecting a variation in current in the LED lighting apparatus in order to detect the failure of the LED lighting apparatus;

FIG. 2 is a view showing the duty cycles of PWM signals that are used to control the on/off operation of an LED light;

FIG. 3 is a block diagram showing the configuration of an apparatus for detecting an error and a variation in LED lighting according to an embodiment of the present invention;

FIG. 4 is a block diagram showing the configuration of a PWM-tail processing unit according to an embodiment of the present invention;

FIG. 5 is a view showing the configuration of a PWM-tail signal;

FIG. 6 is a view illustrating a technology for controlling dimming using a PWM-tail signal;

FIG. 7 is a view illustrating a technology for controlling dimming using a PWM-tail signal;

FIG. 8 is a block diagram showing the configuration of a control unit according to an embodiment of the present invention;

FIG. 9 is a block diagram showing the configuration of an optical feedback unit according to an embodiment of the present invention;

FIG. 10 is a view illustrating a technology for collecting light using an optical feedback unit according to an embodiment of the present invention;

FIG. 11 is a block diagram illustrating the configuration of memory according to an embodiment of the present invention;

FIG. 12 is a flowchart illustrating a method of detecting an error in light control communication according to an embodiment of the present invention;

FIG. 13 is a flowchart illustrating a method of detecting an error in light output control according to an embodiment of the present invention;

FIG. 14 is a flowchart illustrating a method of detecting an error in light output control according to an embodiment of the present invention;

FIG. 15 is a view illustrating a technology for detecting a variation in a lighting environment in a lighting area according to an embodiment of the present invention;

FIG. 16 is a flowchart illustrating a method of detecting a variation in a lighting environment in a lighting area according to an embodiment of the present invention; and

FIG. 17 is a view showing the voltage level of a threshold voltage according to an embodiment of the present invention.

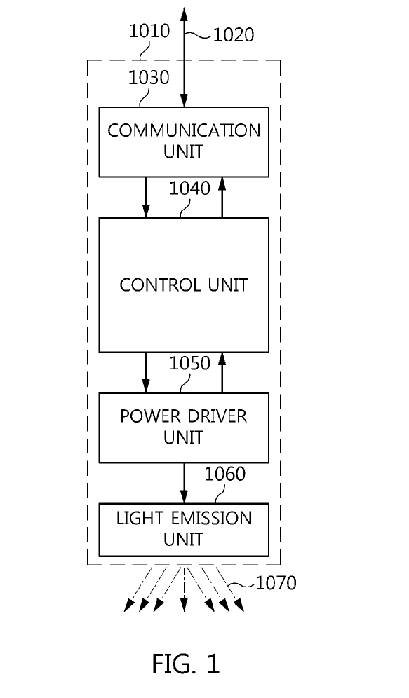

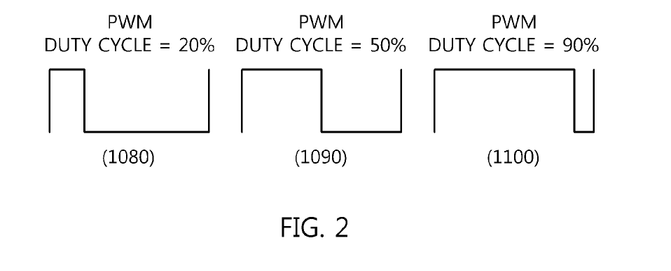

### DESCRIPTION OF THE PREFERRED EMBODIMENTS

The present invention will be described in detail below with reference to the accompanying drawings. Repeated descriptions and descriptions of known functions and configurations which have been deemed to make the gist of the present invention unnecessarily vague will be omitted below. The embodiments of the present invention are intended to fully describe the present invention to a person having ordinary knowledge in the art. Accordingly, the shapes, sizes, etc. of elements in the drawings may be exaggerated to make the description clear.

Embodiments of the present invention will be described in detail with reference to the accompanying drawings below.

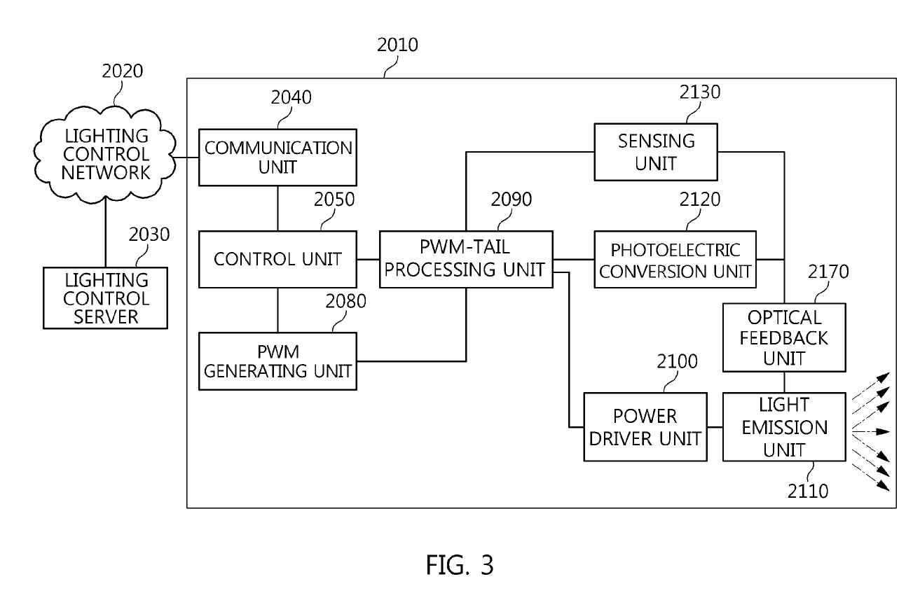

FIG. 3 is a block diagram showing the configuration of an apparatus for detecting an error and a variation in LED lighting according to an embodiment of the present invention.

Referring to FIG. 3, an apparatus 2010 for detecting an error and a variation in LED lighting includes a communication unit 2040, a control unit 2050, a PWM generating unit 2080, a PWM-Tail processing unit 2090, a power driver unit 2100, a light emission unit 2110, a photoelectric conversion unit 2120, a sensing unit 2130, and an optical feedback unit 2170.

The communication unit 2040 communicates with a lighting control server 2030 over a lighting control network 2020.

The control unit 2050 controls individual units that constitute the apparatus 2010 for detecting an error and a variation in LED lighting.

The PWM generating unit 2080 generates a PWM (Pulse Width Modulation) signal including required light emission information.

The required light emission information includes required illuminance information related to the brightness of light and required color information related to RGB colors.

The PWM-Tail processing unit 2090 generates tail data including operation information and a CRC value based on the tail data, and generate PWM-tail signal by combining the tail data, the CRC value, and the PWM signal.

The configuration and operation of the PWM-Tail processing unit 2090 will be described in detail with reference to FIG. 3 below.

The power driver unit 2100 is controlled in response to the PWM-tail signal, and supplies electric power to the light emission unit 2110.

The light emission unit 2110 emits light using at least one LED.

The photoelectric conversion unit 2120 converts the light collected by the optical feedback unit 2170 into an electrical signal.

The sensing unit 2130 senses the illuminance and color of the light collected by the optical feedback unit 2170 using an illuminance sensor and a color sensor.

The optical feedback unit 2170 collects the light emitted from the light emission unit 2110.

The configuration and operation of the optical feedback unit 2170 will be described in detail with reference to FIGS. 7 and 8 below.

Meanwhile, referring to FIG. 8, the control unit 2050 according to an embodiment of the present invention includes memory 2060 and a PWM-Tail control unit 2070.

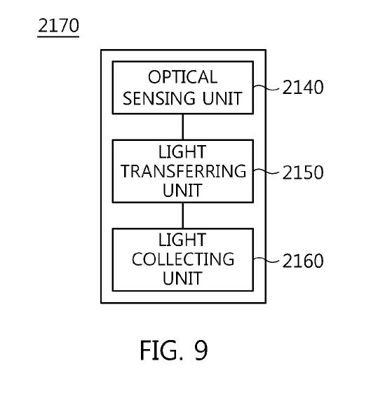

The information stored in the memory 2060 will be described in detail with reference to FIG. 9 below.

The PWM-tail control unit 2070 controls individual units that constitute the apparatus 2010 for detecting an error and a variation in LED lighting.

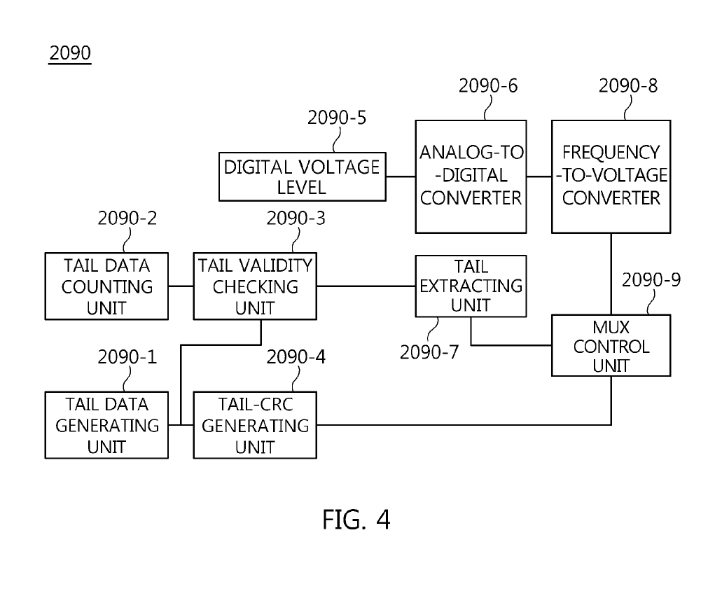

FIG. 4 is a block diagram showing the configuration of the PWM-tail processing unit according to an embodiment of the present invention.

Referring to FIG. 4, the PWM-tail processing unit 2090 according to an embodiment of the present invention includes a tail data generating unit 2090-1, a tail data counting unit 2090-2, a tail validity checking unit 2090-3, a tail-CRC generating unit 2090-4, a digital voltage level 2090-5, an analog-to-digital converter 2090-6, a tail extracting unit 2090-7, a frequency-to-voltage converter 2090-8, and an MUX control unit 2090-9.

The PWM generating unit 2080 generates a PWM signal under the PWM generation control of the control unit 2050.

Further, the tail data generating unit 2090-1 generates tail data under the tail data generation control of the control unit 2050.

When receiving the tail data, the tail-CRC generating unit 2090-4 generates a CRC value based on the tail data, and then generates a tail-CRC signal. Then a PWM-tail signal is generated by combining the tail-CRC signal with the PWM signal. The PWM-tail signal is input to the power driver unit 2100 or fed back to the MUX control unit 2090-9.

The MUX control unit 2090-9 performs control so that either the PWM-tail signal or an electrical signal output from the photoelectric conversion unit 2120 is selected.

In this case, when a setting is made so that the PWM-tail signal is input to the tail extracting unit 2090-7, the tail extracting unit 2090-7 extracts a tail signal from the PWM-tail signal.

The extracted tail signal is input to the tail validity checking unit 2090-3, and then the validity of the tail signal is checked.

If the tail signal is invalid, the control unit 2050 is informed of the state of detecting a lighting control error. If the tail signal is valid, the control unit 2050 is informed that there is no error.

If the tail signal is valid as a result of the checking of the tail validity checking unit 2090-3, the valid tail data of the valid tail signal is transferred to the tail data counting unit 2090-2, the number of pieces of valid tail data is counted, and then the results of the counting are recorded.

The record of the valid tail data obtained by the tail data counting unit 2090-2 is used to measure the time for which lighting has been actually used, and then the results of the measurement are transferred to the control unit 2050.

The signal generated by the optical feedback unit 2170 is input to the photoelectric conversion unit 2120, and then the signal is converted into an electrical signal.

The electrical signal generated by the photoelectric conversion unit 2120 is input to the MUX control unit 2090. If the electrical signal generated by the photoelectric conversion unit 2120 is selected under the control of the MUX control unit 2090-9, the electrical signal is input to the tail extracting unit 2090-7.

The tail validity checking unit 2090-3 checks whether the tail signal extracted by the tail extracting unit 2090-7 is valid.

If the tail signal is invalid, the control unit 2050 is informed of the state of detecting an error in light output. In contrast, if the tail signal is valid, the control unit 2050 is informed that there is no error.

The frequency component of the electrical signal generated by the photoelectric conversion unit 2120 is input to the frequency-to-voltage converter 2090-8. The output of the frequency-to-voltage converter 2090-8 is converted into a voltage level, and then input to the analog-to-digital converter 2090-6.

The analog-to-digital converter 2090-6 determines a threshold voltage based on a bandgap reference voltage.

The output of the analog-to-digital converter 2090 is quantized into a digital voltage level, and the corresponding voltage level is input to the control unit 2050.

The signal generated by the optical feedback unit 2170 is input to the sensing unit 2130, and a sensing result value is input to the control unit 2050.

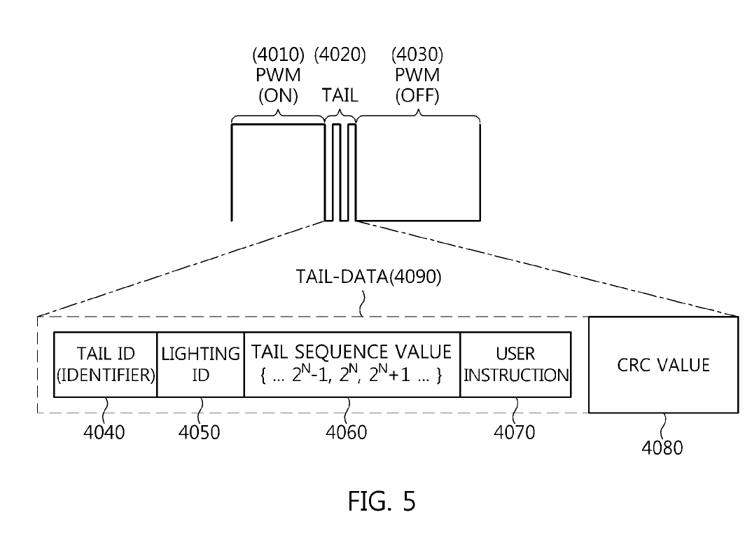

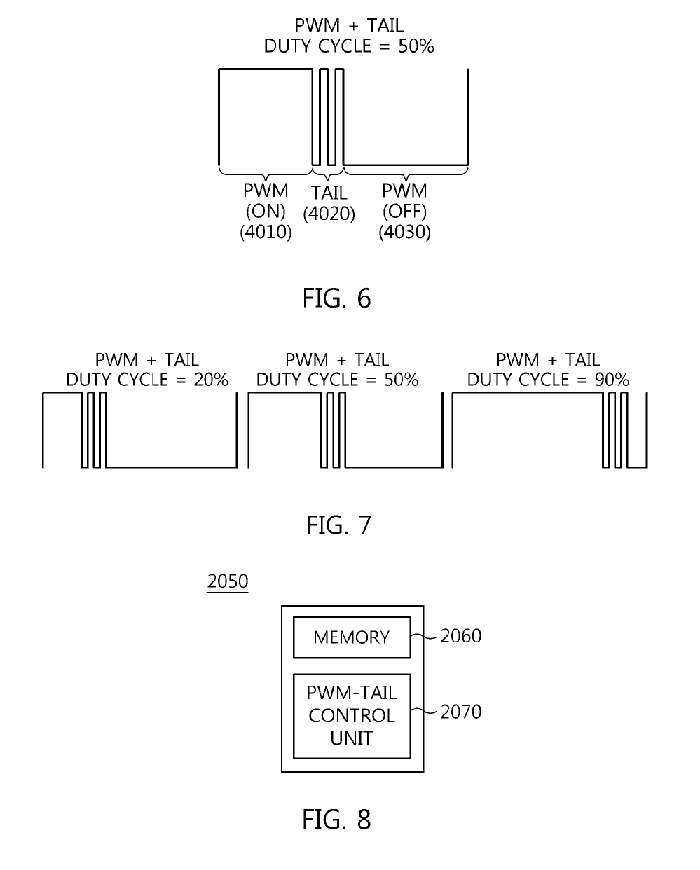

FIG. 5 is a view showing the configuration of the PWM-tail signal, and FIGS. 6 and 7 are views illustrating a technology for controlling dimming using a PWM-tail signal.

The PWM-tail signal includes a PWM ON section 4010, a tail data section 4020, and a PWM OFF section 4030.

The tail data section 4020 includes tail data 4090 and a CRC value 4080.

The tail data 4090 includes a tail ID (identifier) 4040, a lighting ID 4050, a tail sequence value 4060, and user instruction information 4070.

The tail ID 4040 corresponds to identification information that is used to identify the tail data 4090.

The lighting ID 4050 corresponds to the identification information of lighting that is controlled by the tail data.

The tail sequence value 4060 corresponds to the number of signals inside the tail data and the serial number of a signal.

The user instruction information 4070 is information about specific data that will be transferred via the tail data.

The CRC value is code information that is transmitted to check whether an error has occurred in the tail data.

The brightness of lighting is controlled in accordance with the length of the PWM ON section 4010, in which case the tail data section 4020 is excluded from a dimming range.

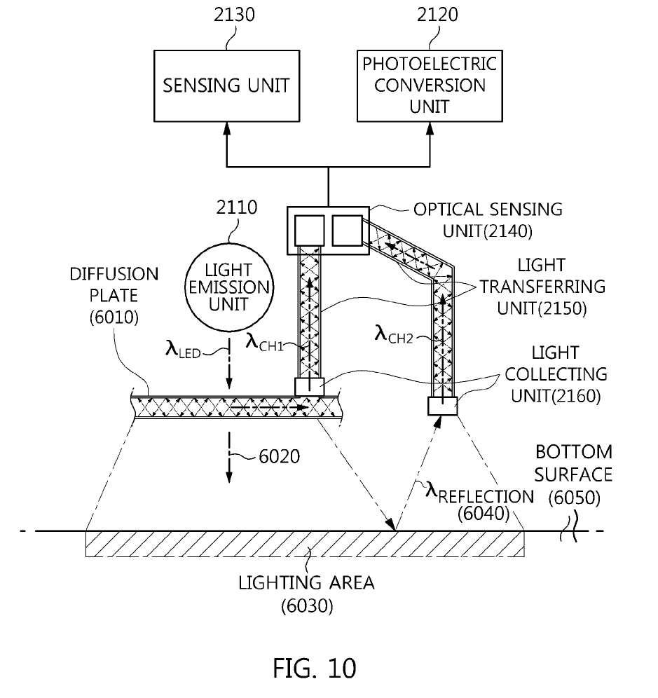

FIG. 9 is a block diagram showing the configuration of the optical feedback unit according to an embodiment of the present invention, and FIG. 10 is a view illustrating a technology for collecting light using an optical feedback unit according to an embodiment of the present invention.

The optical feedback unit 2170 may have at least one light collecting unit 2160. The light collecting unit 2160 has a light transferring unit 2150. The light transferring unit 2150 has a light transfer channel λ_{CH1}, λ_{CH2}, . . . , or λ_{CHn}.

In an embodiment, the light transferring unit 2150 may be implemented as a plastic optical fiber (POF).

The light emission unit 2110 emits light (λ_{LED}) 6020, the light 6020 is output through a diffusion plate 6010. The lighting area 6030 is determined by the beam angle of the light.

When there is no object or moving object in the lighting area 6030, the light (λ_{Reflection}) 6030 reflected from a bottom surface 6050 is input to the light collecting unit 2160 of the optical feedback unit 2170.

The light collecting unit 2160 receives the light reflected from the diffusion plate 6010.

The light transferring unit 2150 is connected to an optical sensing unit 2140, and thus the illuminance and color of the transferred light is sensed by the sensing unit 2130 or an optical signal is converted into an electrical signal through the photoelectric converting unit 2120.

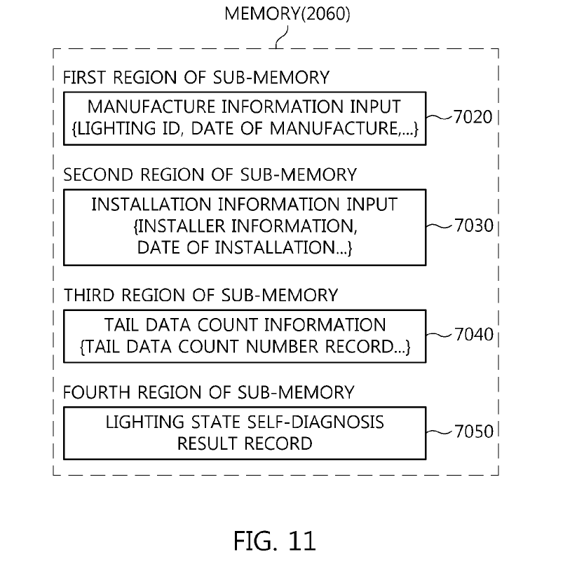

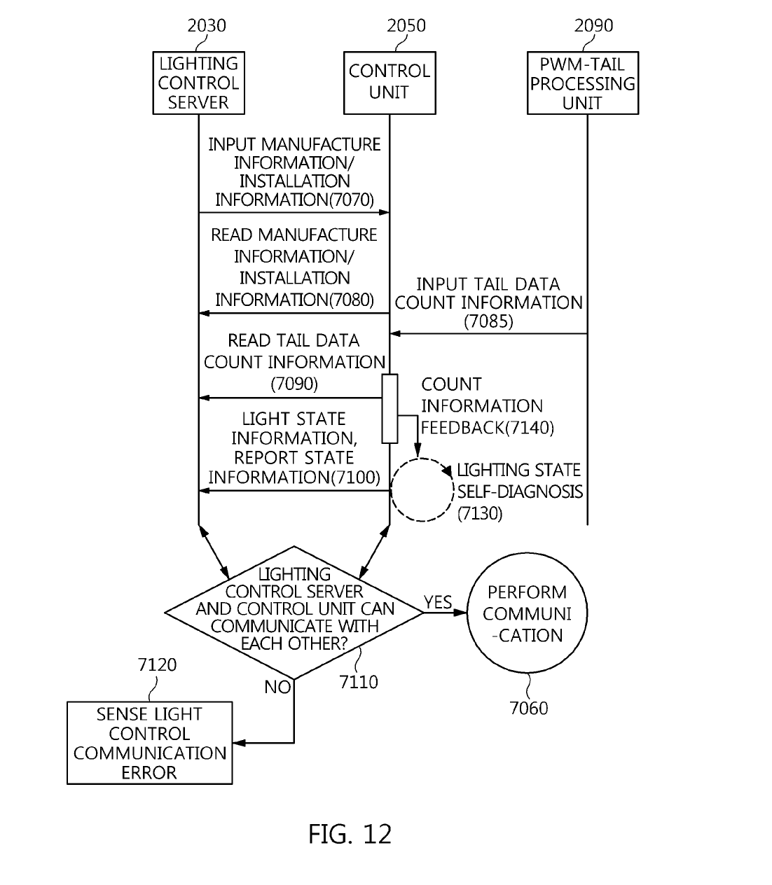

FIG. 11 is a block diagram illustrating the configuration of the memory according to an embodiment of the present invention, and FIG. 12 is a view illustrating a method for detecting an error in light control communication.

Referring to FIG. 11, the memory 2060 may be divided into a plurality of memory regions according to their function. Each of the memory regions may be divided into sub-memory regions 7020, 7030, 7040 and 7050.

Manufacture information (lighting ID, the date of manufacture) 7020, installation information (installer information, the date of installation) 7030, tail data count information (tail data count number record) 7040 and a lighting state self-diagnosis result 7050 are stored in the sub-memory regions.

Meanwhile, referring to FIG. 12, the lighting control server 2030 and the control unit 2050 communicate with each other using a communication execution method 7060.

In the communication execution 7060, the lighting control network 2020 and the communication unit 2040 communicate with each other via two-way communication.

Since the communication unit 2040 is controlled by the control unit 2050, it is assumed in the embodiment of the present invention that the communication execution 7060 is performed between the lighting control server 2030 and the control unit 2050.

However, the communication execution of the present invention is not limited to a specific method.

The manufacture information/installation information is input from the lighting control server 2030 to the control unit 2050 at step 7070.

The manufacture information/installation information of a lighting apparatus is input to the sub-memory region of the control unit 2050, and information about the installation of the lighting apparatus in a building is input to the control unit 2050.

If necessary, the lighting control server 2030 may read the manufacture information and the installation information from the control unit 2050 at step 7080.

This information may be used for the maintenance of lighting.

The PWM-tail processing unit 2090 inputs the tail data count information about the time for which lighting has been actually used to the sub-memory region 7040 of the control unit 2050 to record the tail data information in the sub-memory region 7040. In response to a request from the lighting control server 2030, the PWM-tail processing unit 2090 reads the tail data count information at step 7090, and transfers the tail data count information to the lighting control server 2030, so that the tail data count information is used as a parameter that is used to perform a control function.

The tail data count information 7040 is also used for the lighting state self-diagnosis.

After the tail data count information has been received and the PWM-tail control unit 2070 has input the tail data to the tail data generating unit 2090-1, the PWM-tail control unit 2070 performs the function of the lighting state self-diagnosis by checking whether the same tail data is input to the control unit 2050 at step 7130.

The results of the lighting state self-diagnosis are recorded in the sub-memory region 7050, and the results of the recording are reported as state information at step 7100.

The lighting control server 2030 determines whether communication between the lighting control server 2030 and the control unit 2050 is possible. If communication is possible, it is determined that there is no error. In contrast, if communication is not possible, the lighting control server 2030 provides notification of the state of detecting the light control communication error at step 7120.

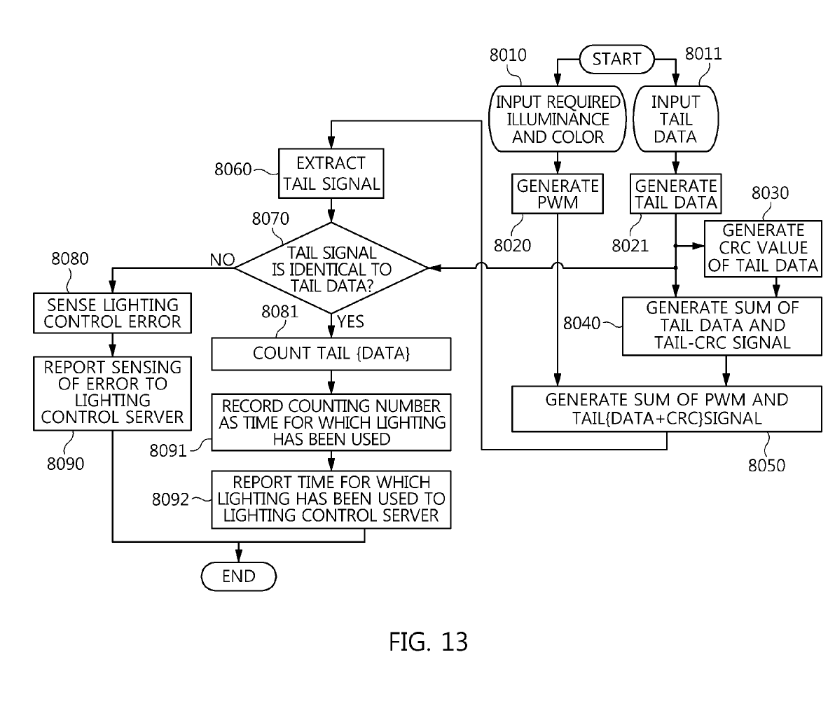

FIG. 13 is a flowchart illustrating a method of detecting an error in light output control according to an embodiment of the present invention.

The lighting control server 2030 inputs the illuminance and color required by a user to the lighting apparatus 2010 over the lighting control network 2020 at step 8010.

A PWM signal is generated by the PWM generating unit 2080 in accordance with the required illuminance and color Req(Av) and Req(Cv) at step 8020.

The lighting apparatus 2010 inputs tail data to the PWM-tail processing unit 2090 under the control of the control unit 2050 at step 8011.

The tail data generating unit 2090-1 generates the tail data at step 8021.

The generated tail data is input to the tail-CRC generating unit 2090-4, so that the CRC value of the tail data is generated at step 8030.

The tail data and the CRC value are summed and then output as a tail-CRC signal Tail{Data+CRC} at step 8040. The tail-CRC signal Tail{Data+CRC} is combined with the generated PWM signal and then generated as a PWM-tail signal at step 8050.

A tail signal is extracted from the PWM-tail signal in order to detect a lighting control error at step 8060.

The tail signal is compared with the tail data by the tail validity checking unit 2090-3 in order to check the validity of the tail signal at step 8070.

If, as a result of the comparison, the tail signal is identical to the tail data, the results of the comparison are used to count the tail data and the results of the counting are used to record the time for which lighting has been used at step 8091.

The time for which lighting has been used may be reported to the lighting control server 2030 at step 8092.

If, as a result of the comparison, the tail signal is not identical to the tail data, a lighting control error is sensed at step 8080 and a signal indicative of the detection of the error is reported to the lighting control server at step 8090.

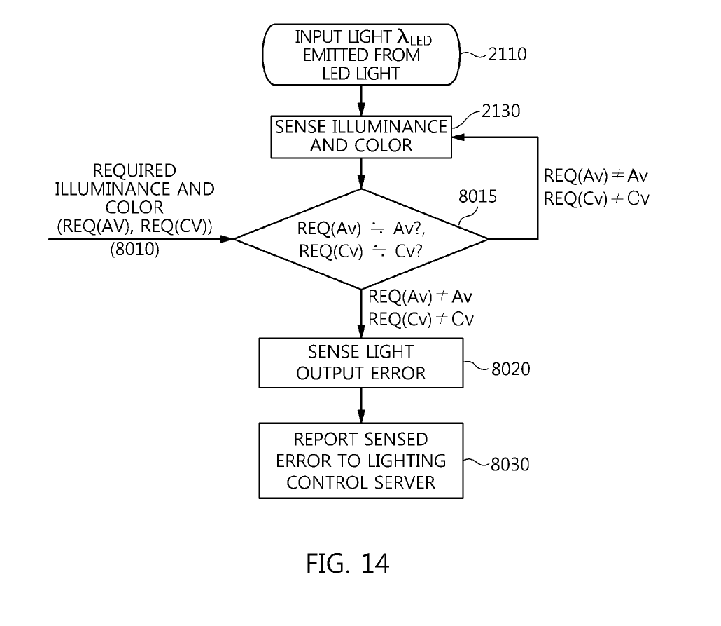

FIG. 14 is a flowchart illustrating a method of detecting an error in light output control according to an embodiment of the present invention.

When light (λ_{LED}) is emitted from the light emission unit 2110, the light is collected by the light collecting unit 2160 and transferred to the optical sensing unit 2140 over the channel λ_{CH1} by Light transferring unit, so that the illuminance and color thereof are sensed at step 2130.

The results of the sensing are output as Av (an illuminance value sensing result) and Cv (a color value sensing result).

In this case, the required illuminance and color Req(Av) and Req(Cv) (see step 8010 of FIG. 10) are compared with the results of the sensing at step 8015.

If, as a result of the comparison, the required values are identical to the sensed values or fall within a range defined by the user ({Req(Av)=Av, Req(Cv)=Cv} or {Req(Av)≈Av, Req(Cv)≈Cv}), the illuminance and color are continuously sensed.

If, as a result of the comparison, the required values are different from the sensed values ({Req(Av)≠Av, Req(Cv)≠Cv}), it is determined that a light output error has occurred at step 8020 and a result value thereof is reported to the lighting control server 2030 at step 8030.

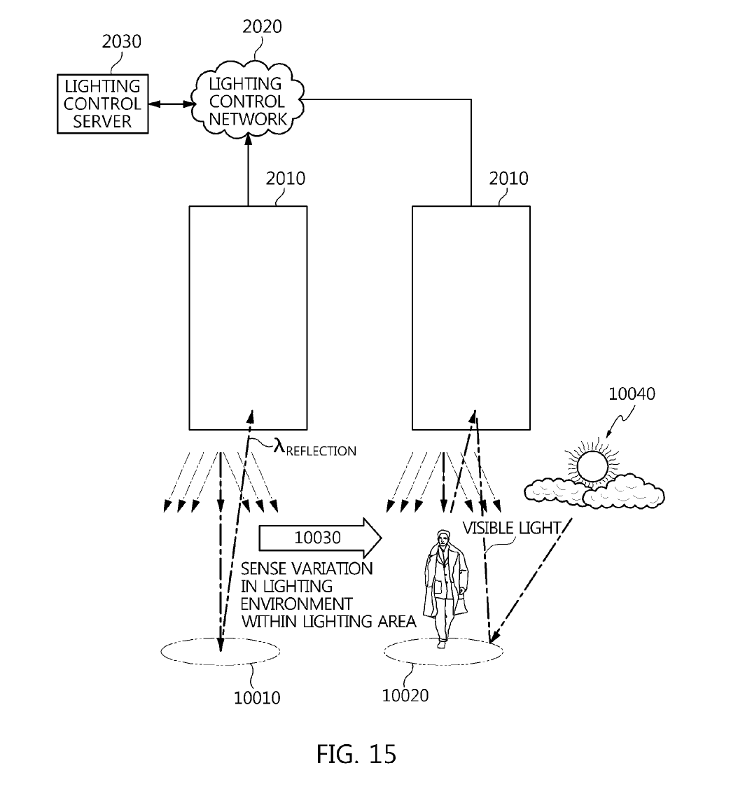

FIG. 15 is a view illustrating a technology for detecting a variation in a lighting environment according to an embodiment of the present invention.

The lighting apparatus 2010 is connected to the lighting control server 2030 over the lighting control network 2020, and is controlled by the lighting control server 2030.

In this case, the lighting apparatus 2010 emits visible light, and the light (λ_{Reflection}) 6040 reflected from the bottom surface 6050 in the lighting area 6030 is input to the lighting apparatus 2010.

Since a case in which there is no moving object, no thing or no object within the lighting area 6030 differs from a case in which a variation in situation occurs due to a moving object or a variation in illuminance occurs due to daylight 10040 in terms of the frequency component and amount of light of reflected light (λ_{Reflection}) 6040, the lighting apparatus senses a variation in the light environment within the lighting area using the above-described difference.

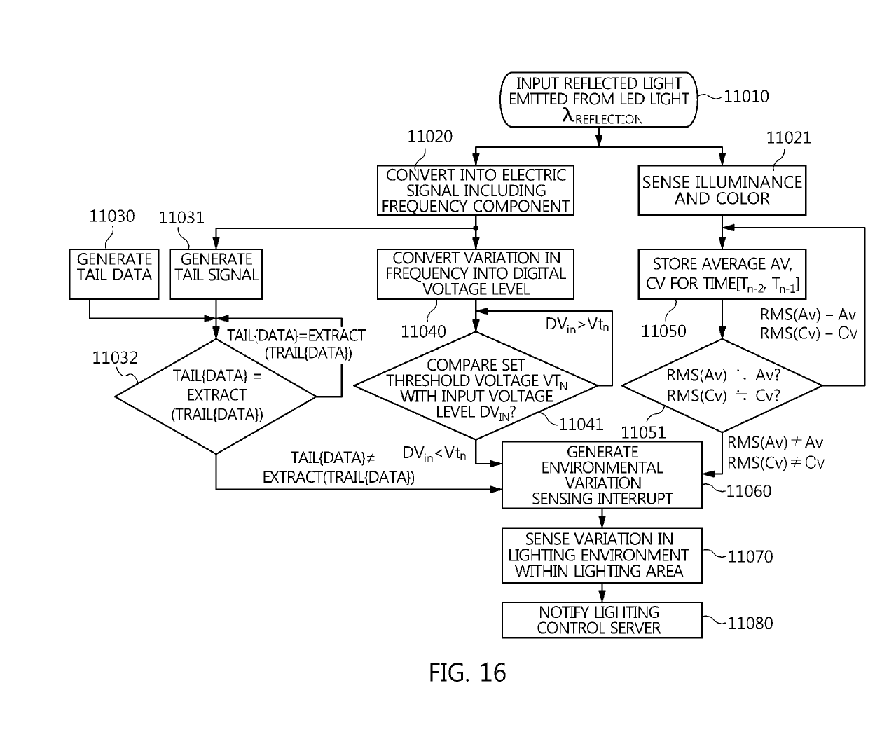

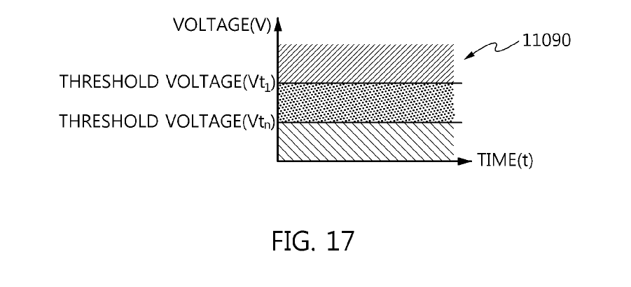

FIG. 16 is a flowchart illustrating a method of detecting a variation in a lighting environment in a lighting area according to an embodiment of the present invention, and FIG. 17 is a view showing the voltage level of a threshold voltage according to an embodiment of the present invention.

The light emitted from the light emission unit 2110 is reflected from the bottom surface 6050 in the lighting area 6030, so that the reflected light 6040 is input to the optical feedback unit 2170 at step 11010.

The input reflected light 6040 is converted into a photoelectric signal by the photoelectric conversion unit 2120 at step 1120, in which case the photoelectric signal is converted into an electric signal including a frequency component.

The signal including a frequency component is converted into a digital voltage level via the frequency-to-voltage converter 2090-8 and the analog-to-digital converter 2090-6 at step 11040.

The output is denoted as DVin and is compared with the threshold voltage Vtn and an input voltage level DVin by the control unit 2050 at step 11041.

Although the comparison is continuously performed if DVin>Vtn, an environmental variation sensing interrupt is generated if DVin<Vtn at step 11060.

The tail signal is extracted from the signal output from the optical conversion unit 2120 at step 11031, and validity is checked by comparing the tail data, generated at step 11030, with the tail signal at step 11032.

If, as a result of the validity checking, the tail data is not identical to the tail signal (Tail{Data}≠Extract(Tail {Data })), the environmental variation sensing interrupt is generated at step 11060.

The reflected light 6040 is input to the optical feedback unit 2170 and the sensing unit 2130 senses the illuminance and color of the reflected light 6040 at step 11021.

The information of the sensing results Av and Cv of the illuminance and the color is measured for a predetermined time ([Tn−2 and Tn−1]) set by a user and the average values of the measured information are obtained and then stored at step 11050.

The average values RMS(Av) and RMS(Cv), which are obtained by storing the sensing results Av and Cv for the predetermined time, are compared with the current sensing results Av and Cv of the illuminance and color at step 11051.

If, as a result of the comparison, the average values RMS(Av) and RMS(Cv) deviate from the range set by the user (RMS(Av)≠Av, RMS(Cv)≠Cv), an environmental variation sensing interrupt is generated at step 11060.

If the environmental variation sensing interrupt is generated, it is determined that a variation in the light environment of the lighting area has occurred and the lighting control server 2030 is informed of the fact at step 11080.

In accordance with the present invention, three types of errors in a lighting apparatus (an error in lighting control communication, an error in light control, and an error in light output) can be sensed, and a variation in a lighting environment in a lighting area can be sensed, using a PWM-tail technology.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of detecting an error and a variation in Light-Emitting Diode (LED) lighting, the method comprising:
generating a Pulse-Width Modulation (PWM) signal including required light emission information;
generating tail data including operation information;
generating a Cyclic Redundancy Code (CRC) value based on the tail data;
generating a tail-CRC signal by combining the tail data with the CRC value; and
generating a PWM-tail signal by combining the tail-CRC signal with the PWM signal.

2. The method of claim 1, further comprising:
extracting a tail signal from the PWM-tail signal; and
checking validity of the extracted tail signal and then reporting results of the checking to a lighting control server.

3. The method of claim 2, wherein checking the validity of the extracted tail signal and then reporting the results of the checking to the lighting control server comprises:
if the tail signal is valid, counting the tail data of the tail signal and then recording a time for which lighting has been used; and
reporting the time for which lighting has been used to the lighting control server.

4. The method of claim 2, wherein checking the validity of the extracted tail signal and then reporting the results of the checking to the lighting control server comprises:
if the tail signal is invalid, determining that a lighting control error has occurred; and
reporting the lighting control error to the lighting control server.

5. The method of claim 1, further comprising:
supplying electric power to a light emission unit in response to the PWM-tail signal; and
emitting light from the light emission unit in response to the supplied electric power.

6. The method of claim 5, further comprising:
collecting the light emitted from the light emission unit;
sensing illuminance and color of the collected light;
comparing the sensed illuminance and color of the light with the required light emission information; and
reporting to the lighting control server whether a light output error has occurred based on results of the comparison that are obtained by the comparing the sensed illuminance and color of the light with the required light emission information.

7. The method of claim 5, further comprising:
collecting the light emitted from the light emission unit;
converting the collected light into an electrical signal including a frequency component;
extracting a tail signal from the electrical signal; and
checking validity of the extracted tail signal, and then reporting results of the checking to a lighting control server.

8. The method of claim 7, wherein checking the validity of the extracted tail signal, and then reporting the results of the checking to the lighting control server comprises:
if the tail signal is invalid, determining that an environmental variation has occurred; and
reporting the environmental variation to the lighting control server.

9. The method of claim 5, further comprising:
collecting the light emitted from the light emission unit;
converting the collected light into an electrical signal including a frequency component;
converting the electrical signal into a digital voltage level into which the frequency component has been incorporated;
comparing the digital voltage level with a predetermined threshold voltage; and
reporting to a lighting control server whether an environmental variation has occurred based on results of the comparison obtained by comparing the digital voltage level with the predetermined threshold voltage.

10. The method of claim 9, wherein reporting to the lighting control server whether the environmental variation has occurred based on the results of the comparison comprises:
if the digital voltage level is lower than the predetermined threshold voltage, determining that the environmental variation has occurred; and
reporting the environmental variation to the lighting control server.

11. The method of claim 5, further comprising:
collecting the light emitted from the light emission unit;
sensing illuminance and color of the collected light;
extracting average values of the illuminance and the color by storing the sensed illuminance and color of the light over a predetermined time;
comparing the average values of the illuminance and the color with the required light emission information; and
reporting to the lighting control server whether an environmental variation has occurred based on results of the comparison obtained by comparing the average values of the illuminance and the color with the required light emission information.

12. The method of claim 11, wherein reporting to the lighting control server whether the environmental variation has occurred based on the results of the comparison comprises:
if the average values of the illuminance and the color are different from the required light emission information, determining that the environmental variation has occurred; and
reporting the environmental variation to the lighting control server.

13. The method of claim 11, wherein the operation information comprises a tail identifier, a lighting identifier, a tail sequence value, and user instruction information.

14. An apparatus for detecting an error and a variation in LED lighting, the apparatus comprising:
a communication unit configured to make communication with a lighting control server over a lighting control network;
a PWM generating unit configured to generate a PWM signal including required light emission information;
a PWM-tail processing unit configured to generate tail data including operation information and a CRC value based on the tail data, and to generate a PWM-tail signal by combining the tail data, the CRC value and the PWM signal;
a light emission unit configured to emit light using at least one LED;
a power driver unit configured to supply electric power to the light emission unit under control of the PWM-tail signal;
an optical feedback unit configured to collect the light emitted from the light emission unit;
a photoelectric conversion unit configured to convert the light collected in the optical feedback unit into an electrical signal; and
a sensing unit configured to sense illuminance and color of the light collected by the optical feedback unit by using an illuminance sensor and a color sensor.

15. The apparatus of claim 14, wherein the PWM-tail processing unit extracts a tail signal from the PWM-tail signal, and checks validity of the extracted tail signal, thereby detecting whether a lighting control error has occurred.

16. The apparatus of claim 14, wherein the PWM-tail processing unit extracts a tail signal from the PWM-tail signal, and counts tail data of the extracted tail signal, thereby obtaining a time for which lighting has been used.

17. The apparatus of claim 14, wherein the PWM-tail processing unit senses whether a light output error has occurred by comparing the sensed illuminance and color of the light, sensed by the sensing unit, with the required light emission information.

18. The apparatus of claim 14, wherein the PWM-tail processing unit extracts a tail signal from the electrical signal obtained by the photoelectric conversion unit, and checks validity of the extracted tail signal, thereby detecting whether an environmental variation has occurred.

19. The apparatus of claim 14, wherein the PWM-tail processing unit converts the electrical signal obtained by the photoelectric conversion unit into a digital voltage level into which a frequency component has been incorporated, and compares the digital voltage level with a predetermined threshold voltage, thereby detecting whether an environmental variation has occurred.

20. The apparatus of claim 14, wherein the PWM-tail processing unit extracts average values of the illuminance and color by storing the illuminance and color sensed by the sensing unit over a predetermined time, and compares the average values of the illuminance and the color with the required light emission information, thereby detecting whether an environmental variation has occurred.
